(19) United States
(12) Patent Application Publication
(10) Pub. No.: US 2002/0141151 A1
(43) Pub. Date: Oct. 3, 2002

(54) Server with six sets of hard disk drivers

(76) Inventors: Chien Ying Chen, Yungho City (TW); Frederick James Nemec, Tustin, CA (US)

Correspondence Address: ROSENBERG, KLEIN & LEE, 3458 ELLICOTT CENTER DRIVE-SUITE 101, ELLICOTT CITY, MD, 21043, US

(21) Appl. No.: 09/819,747

(22) Filed: Mar. 29, 2001

(51) Int. Cl. G06F 1/20; H05K 7/20

(52) U.S. Cl. 361/687; 361/683; 361/724

(57) ABSTRACT

A server comprises six sets of hard disk drivers as well as a floppy disk driver and an optical disk driver. The floppy disk driver adopts a compact floppy disk driver used for notebook and the optical disk driver adopts a compact optical disk driver used for notebook computer to reduce occupied volume. Therefore, the number of the hard disk drivers is increased to expand data storage capacity without increasing physical size.

### FIELD OF THE INVENTION

The present invention relates to a server with six sets of hard disk drivers, especially to a hard disk driver expansion mechanism for an industrial computer server to expand the data capacity of the industrial computer server without increasing physical size.

### BACKGROUND OF THE INVENTION

FIG. 1 shows a prior art industrial computer server, which comprises a main body 10 of rectangular shape. The main body 10 is provided with four sets of hard disk drivers 101 on front side thereof and arranged in stacking fashion. The industrial computer server further comprises a floppy disk driver 102 and an optical disk driver 103 in front of the main body 10 and arranged on one side of the main body 10. The floppy disk driver 102 is stacked atop the optical disk driver 103. The main body 10 further has a pulling grip 20 in front side thereof. The main body 10 can be pulled out by handling the pulling grip 20 for maintenance and examination.

However, in above-mentioned industrial computer server, the main body 10 is designed to contain only four sets of hard disk drivers 101. If the data storage capacity of the industrial computer server is not enough, another main body 10 is required. Nevertheless, the additional floppy disk driver 102 and optical disk driver 103 are wasted.

Moreover, the main body 10 has a specific volume to accommodate four sets of hard disk drivers 101 as well as the floppy disk driver 102 and optical disk driver 103. The additional main body 10 is hard to arrange if the existing space is not enough.

### SUMMARY OF THE INVENTION

It is the object of the present invention to provide a server with six sets of hard disk drivers to expand the data capacity of the industrial computer server without increasing physical size.

To achieve the above object, the server comprises six sets of hard disk drivers as well as a floppy disk driver and an optical disk driver. The floppy disk driver adopts a compact floppy disk driver used for notebook and the optical disk driver adopts a compact optical disk driver used for notebook computer to reduce occupied volume. Therefore, the number of the hard disk drivers is increased to expand data storage capacity without increasing physical size.

The various objects and advantages of the present invention will be more readily understood from the following detailed description when read in conjunction with the appended drawing, in which:

### BRIEF DESCRIPTION OF DRAWINGS

FIG. 1 is a sectional view of prior art industrial computer server;

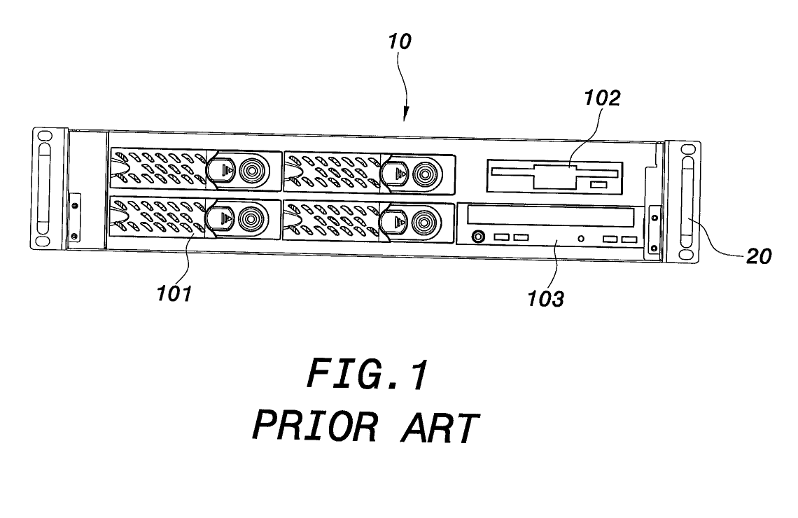

FIG. 2 is the sectional view of the present invention;

FIG. 3 is the perspective view of the present invention;

FIG. 4 shows another preferred embodiment of the present invention.

### DETAILED DESCRIPTION OF THE INVENTION

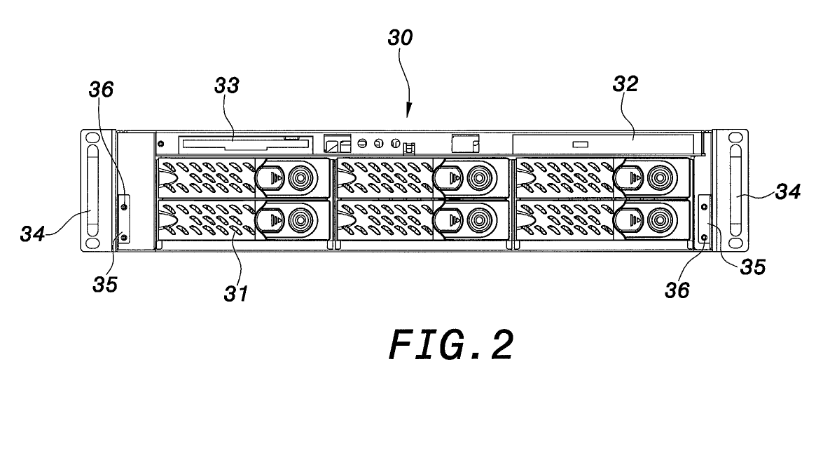

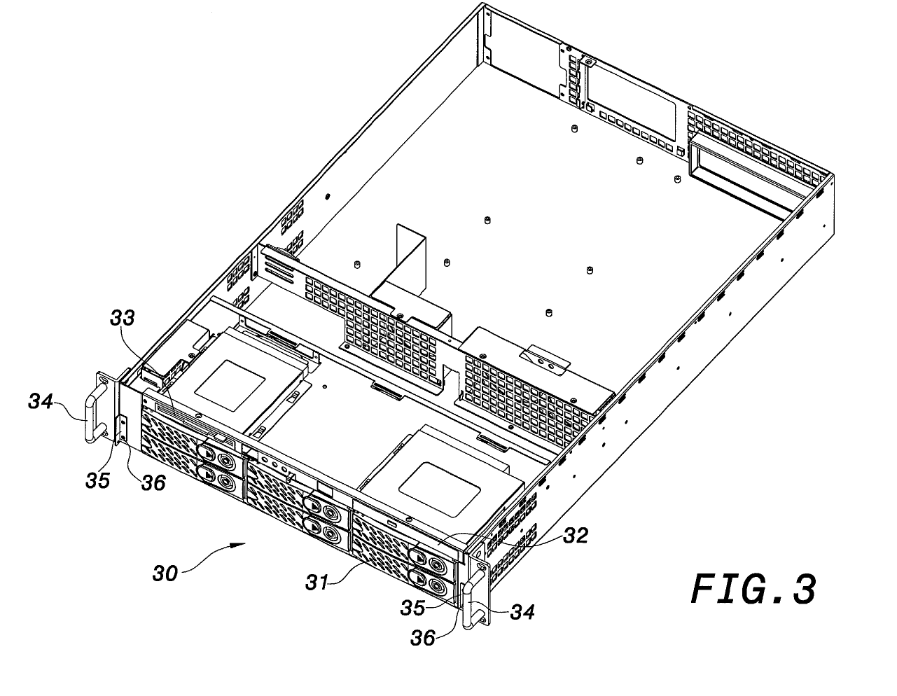

With reference now to FIGS. 2 and 3, the present invention provides a server with six sets of hard disk drivers, especially provides a hard disk driver expansion mechanism for an industrial computer server to expand the data capacity of the industrial computer server without increasing physical size. The industrial computer server of the present invention comprises a main body 30 with a fixed size. The main body 30 is of rectangular shape and has six sets of hard disk drivers in front side thereof and arranged in stacking fashion. The industrial computer server further comprises a compact floppy disk driver 32 used for notebook computer, and a compact optical disk driver 33 also used for notebook computer, in front of the main body 30. The compact floppy disk driver 32 and the optical disk driver 33 are arranged in stacking fashion and on one side of the main body 30. The main body 30 further comprises two accommodating tanks 35 on both front sides thereof and each accommodating tank 35 has a plurality of sockets 36, which can be used for earphone or other peripherals. The main body 30 further has two pulling grips 34 on both front sides thereof. The main body 30 can be pulled out by handling the pulling grip 20 for maintenance and examination.

With reference now to FIGS. 2 and 3, the main body 30 of fixed size can accommodate six sets of hard disk drivers 31 as well as a compact floppy disk driver 32 and a compact optical disk driver 33. Therefore, the main body 30 can provide larger data storage capacity without increasing occupation size.

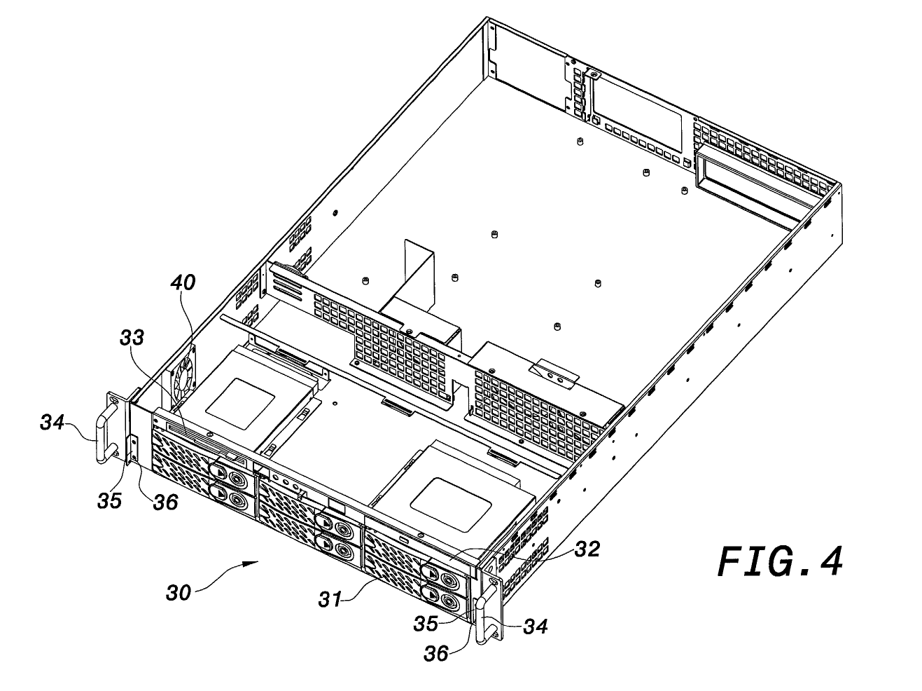

FIG. 4 shows another preferred embodiment of the present invention, a heat-dissipation fan 40 is arranged on one side of the main body 30 to reduce temperature in the main body 30. The other arrangements of the main body 30 are same as previous preferred embodiment of the present invention.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

I claim:

1. A server with six sets of hard disk drivers, the server comprising
a main body of rectangular shape;
six sets of hard disk drivers in front of the main body and arranged in stacking fashion;
a compact floppy disk driver used for notebook computer and a compact optical disk driver used for notebook computer in front of the main body and arranged in stacking fashion; and
two pulling grips on both front sides of the main body.

2. The server with six sets of hard disk drivers as in claim 1, wherein a heat-dissipation fan is arranged on one side of the main body.
